(19) United States
(12) Patent Application Publication
(10) Pub. No.: US 2025/0098193 A1
(43) Pub. Date: Mar. 20, 2025

(54) SEMICONDUCTOR DEVICE

(71) Applicant: Renesas Electronics Corporation, Tokyo (JP)

(72) Inventor: Nao NAGATA, Tokyo (JP)

(21) Appl. No.: 18/780,767

(22) Filed: Jul. 23, 2024

(30) Foreign Application Priority Data
Sep. 15, 2023 (JP) 2023-149992

(51) Int. Cl. H01L 29/739; H01L 29/06; H01L 29/423

(52) U.S. Cl. CPC H10D 12/481; H10D 62/103; H10D 62/127; H10D 64/513

(57) ABSTRACT

According to one embodiment, the semiconductor device 1 includes a semiconductor substrate having an upper surface and a lower surface, and an emitter wiring, wherein when viewed from the upper surface side, the semiconductor substrate has an active region including a plurality of IGBTs, a termination region, and a main junction region, wherein the semiconductor substrate of the main junction region has an N− type drift layer and a P type junction impurity layer, wherein the semiconductor substrate of the termination region has an N− type drift layer and a P type floating layer, wherein at least the main junction region has a trench electrode provided inside the trench, and a trench insulating film provided between the trench electrode and the semiconductor substrate, and wherein the trench electrode and the P type junction impurity layer are connected to the emitter wiring.

### CROSS-REFERENCE TO RELATED APPLICATIONS

The disclosure of Japanese Patent Application No. 2023-149992 filed on Sep. 15, 2023, including the specification, drawings and abstract is incorporated herein by reference in its entirety.

### BACKGROUND

This disclosure relates to a semiconductor device, for example, a semiconductor device including IGBT (Insulated Gate Bipolar Transistor) and FWD (Free Wheeling Diode), as well as a semiconductor device including RC-IGBT (Reverse Conducting-IGBT). Patent Document 1 describes a semiconductor device having an IGBT.

### PRIOR ART DOCUMENTS

### Patent Literature

[Patent Document 1] Japanese Unexamined Patent Application Publication No. 2017-079308

### SUMMARY

Electric field concentration in a semiconductor device causes the occurrence of Single Event Burn-out (hereinafter referred to as SEB). A semiconductor device that can mitigate electric field concentration and reduce the occurrence rate of SEB is desired.

Other problems and novel features will become apparent from the description and the accompanying drawings of this specification.

According to one embodiment, a semiconductor device includes a semiconductor substrate having a first main surface and a second main surface opposite the first main surface; and an emitter wiring provided on the first main surface via an insulating film, wherein when viewed from the first main surface side, the semiconductor substrate includes an active region includes a plurality of IGBTs formed on the semiconductor substrate; a termination region arranged to surround the active region; and a main junction region arranged between the active region and the termination region, wherein the semiconductor substrate of the main junction region includes a drift layer of a first conductivity type; and a junction impurity layer of a second conductivity type provided closer to the first main surface side than the drift layer, wherein the semiconductor substrate in the termination region includes the drift layer; and a floating layer of the second conductivity type provided closer to the first main surface side than the drift layer, wherein at least the main junction region of the semiconductor substrate includes a trench electrode provided inside a trench formed in the first main surface; and a trench insulating film provided between the trench electrode and the semiconductor substrate, wherein when viewed from the first main surface side, the trench electrode includes a portion extending in one direction from the main junction region towards the termination region, and wherein the trench electrode and the junction impurity layer are connected to the emitter wiring in the main junction region.

According to one embodiment, a semiconductor device includes a semiconductor substrate having a first main surface and a second main surface opposite the first main surface; and an emitter wiring provided on the first main surface via an insulating film, wherein when viewed from the first main surface side, the semiconductor substrate includes an active region includes a plurality of IGBTs formed on the semiconductor substrate; a termination region arranged to surround the active region; and a main junction region arranged between the active region and the termination region, wherein the semiconductor substrate of the main junction region includes a drift layer of a first conductivity type; and a junction impurity layer of a second conductivity type provided closer to the first main surface side than the drift layer, wherein the semiconductor substrate in the termination region includes the drift layer; and a floating layer of the second conductivity type provided closer to the first main surface side than the drift layer, wherein at least the main junction region of the semiconductor substrate includes a trench electrode provided inside a trench formed in the first main surface; and a trench insulating film provided between the trench electrode and the semiconductor substrate, wherein when viewed from the first main surface side, the trench electrode includes a portion extending in one direction from the active region towards the termination region, and wherein the trench electrode and the junction impurity layer are connected to the emitter wiring in the main junction region, wherein the IGBT includes the drift layer; a barrier layer of the first conductivity type provided closer to the first main surface side than the drift layer; a channel layer of the second conductivity type provided closer to the first main surface side than the barrier layer; emitter layer of the first conductivity type provided closer to the first main surface side than the channel layer; gate trench electrodes provided so as to sandwich the barrier layer, the channel layer, and the emitter layer in another direction crossing the one direction in a plane parallel to the first main surface; a gate trench insulating film provided between each of the gate trench electrodes and the semiconductor substrate.

According to the embodiment, it is possible to provide a semiconductor device that can reduce the occurrence rate of SEB.

### BRIEF DESCRIPTION OF THE DRAWINGS

FIG. 1 is a plan view illustrating a semiconductor device according to a reference example.

FIG. 2 is a cross-sectional view illustrating the semiconductor device according to the reference example, showing the cross-section along line II in FIG. 1.

FIG. 3 is a schematic diagram illustrating a simulation result of electric field strength distribution when a reverse bias is applied to the collector in the semiconductor device according to the comparative example.

FIG. 4 is a schematic diagram illustrating a simulation result of electric field strength distribution when a reverse bias is applied to the collector in the semiconductor device according to the comparative example, and is an enlarged view of part IV in FIG. 3.

FIG. 5 is a graph illustrating the electric field strength distribution when a reverse bias is applied to the collector in the semiconductor device according to the comparative example, where the horizontal axis indicates the position in the direction from the active region of the semiconductor device to the termination region, and the vertical axis indicates the electric field strength.

FIG. 6 is a plan view illustrating a semiconductor device according to a first embodiment.

FIG. 7 is a plan view illustrating the semiconductor device according to the comparative example, showing an enlarged view of part VII in FIG. 6.

FIG. 8 is a cross-sectional view illustrating a main junction region and a termination region of the semiconductor device related to the comparative example, showing the cross-section along line VIII-VIII of FIG. 7.

FIG. 9 is a cross-sectional view illustrating the IGBT formed on the semiconductor substrate in the semiconductor device related to the comparative example, showing the cross-section along line IX-IX of FIG. 7.

FIG. 10 is a plan view illustrating the semiconductor device according to the first embodiment, with an enlarged view of part X of FIG. 6.

FIG. 11 is a cross-sectional view illustrating the semiconductor device according to the first embodiment, showing the cross-section along line XI-XI of FIG. 10.

FIG. 12 is a cross-sectional view illustrating the semiconductor device according to the first embodiment, showing the cross-section along line XII-XII of FIG. 10.

FIG. 13 is a plan view illustrating a semiconductor device according to a first modification example of the first embodiment.

FIG. 14 is a cross-sectional view illustrating the semiconductor device according to the first modification example of the first embodiment, showing the cross-section along line XIV-XIV of FIG. 13.

FIG. 15 is a plan view illustrating a semiconductor device according to a second modification example of the first embodiment.

FIG. 16 is a plan view illustrating another example of a semiconductor device according to another version of the second modification example.

FIG. 17 is a plan view illustrating a semiconductor device according to a third modification example of the first embodiment.

FIG. 18 is a plan view illustrating a simulation result of the electric field strength distribution at the boundary between the main junction region and the termination region in the semiconductor device related to the comparative example.

FIG. 19 is a plan view illustrating a simulation result of the electric field strength distribution at the boundary between the main junction region and the termination region in the semiconductor device according to the first embodiment.

FIG. 20 is a perspective view illustrating a simulation result of the electric field strength distribution at the boundary between the main junction region and the termination region in the semiconductor device related to the comparative example, showing the cross-sectional perspective along line XX-XX of FIG. 18.

FIG. 21 is a perspective view illustrating a simulation result of the electric field strength distribution at the boundary between the main junction region and the termination region in the semiconductor device according to the first embodiment, showing the cross-sectional perspective along line XXI-XXI of FIG. 19.

FIG. 22 is a cross-sectional view illustrating a simulation result of the electric field strength distribution at the boundary between the main junction region and the termination region in the semiconductor device related to the comparative example.

FIG. 23 is a cross-sectional view illustrating a simulation result of the electric field strength distribution at the boundary between the main junction region and the termination region in the semiconductor device according to the first embodiment.

FIG. 24 is a graph illustrating the electric field strength distributions of the semiconductor device related to the comparative example and the semiconductor device according to the first embodiment, where the horizontal axis indicates the position at the boundary between the main junction region and the termination region, and the vertical axis indicates the electric field strength.

FIG. 25 is a graph illustrating the collector breakdown voltages of the semiconductor device related to the comparative example and the semiconductor device according to the first embodiment, where the horizontal axis indicates the collector voltage, and the vertical axis indicates the leak current.

FIG. 26 is a plan view illustrating a semiconductor device according to a second embodiment.

FIG. 27 is a cross-sectional view illustrating the semiconductor device according to the second embodiment, showing the cross-section along line XXVII-XXVII of FIG. 26.

FIG. 28 is a plan view illustrating a semiconductor device according to a third embodiment.

### DETAILED DESCRIPTION

For the sake of clarity in the explanation, the following descriptions and drawings have been appropriately omitted and simplified. Furthermore, in the drawings, hatching and the like may be omitted in cross-sections when it would otherwise make the drawing too complicated or when the distinction from voids is clear. Note that in each drawing, the same elements are designated by the same reference numerals, and redundant explanations will be omitted as necessary. In addition, symbols are omitted as appropriate to avoid cluttering the diagram.

First, in <Cosmic ray resistance>, cosmic ray resistance regarding the occurrence of SEB in semiconductor devices will be explained. In <Reference Example>, a semiconductor device according to a reference example will be described. In <Problems Newly Found by the Inventor>, a semiconductor device of a comparative example will be explained, and then a problem newly discovered by the inventor will be explained regarding the semiconductor device of a comparative example. In <First embodiment>, a semiconductor device according to first embodiment will be described. At this time, a comparative example of <semiconductor device of comparative example> and an embodiment of <semiconductor device of first embodiment> will be compared and explained. Thereafter, in <Second embodiment> and <Third embodiment>, semiconductor devices of each embodiment will be described. Note that the cosmic ray resistance, the semiconductor devices according to the reference example and the comparative example, and the problems newly discovered by the inventor regionlso within the scope of the technical idea of the embodiment.

### Cosmic Ray Resistance

Power devices including IGBTs, diodes, etc. are required to have resistance (referred to as cosmic ray resistance) to cosmic rays (also called cosmic radiation). For example, industrial products and automotive products are required to have severe cosmic ray resistance of several FIT/chip or less. Cosmic ray resistance is probabilistic resistance to neutron radiation.

When cosmic rays arrive at Earth, they react with oxygen, nitrogen, etc. in the atmosphere and generate secondary particles. The generated secondary particles still have high energy and further react with oxygen, nitrogen, etc. in the atmosphere. Due to this cascade reaction, neutrons fall on the ground as neutron beams. Neutron beams cause errors that cause semiconductor devices to malfunction.

For example, an error occurs in the semiconductor device due to the interaction between the semiconductor device and a high-energy neutron beam as described below. That is, first, a high-energy neutron beam enters the semiconductor device. This causes a nuclear reaction between the neutron beam and the atoms that make up the semiconductor. Then, secondary particles are generated. The generated secondary particles enter the sensitive region. This causes a single event phenomenon. The single event phenomenon is a general term for phenomena such as malfunctions and damage that occur when single particles containing protons and heavy ions such as He ions and Fe ions are incident on semiconductor devices.

This single event phenomenon causes soft errors and hard errors. A problem with power devices including IGBTs, diodes, etc. is mainly hard errors including single event burn-out (hereinafter referred to as SEB). In short, cosmic rays are converted into high-energy neutron beams before they enter the semiconductor chip (neutron beams cannot be shielded). Then, the neutron beam that enters the high electric field region within the semiconductor chip generates secondary particles, which cause a hard error due to the single event phenomenon.

As the manufacturing process of semiconductor devices becomes more miniaturized, the cosmic ray resistance of semiconductor devices decreases. Therefore, one challenge is to improve cosmic ray resistance against malfunctions caused by such neutron beams.

To improve cosmic ray resistance, for example, one method is to increase the thickness of the n-type drift layer in the semiconductor chip to reduce the electric field strength. However, increasing the thickness of the semiconductor chip worsens performance such as collector-emitter saturation voltage VCE (sat) and switching (SW) losses. Therefore, there is a trade-off relationship between cosmic ray resistance and the performance of power devices.

### Reference Example

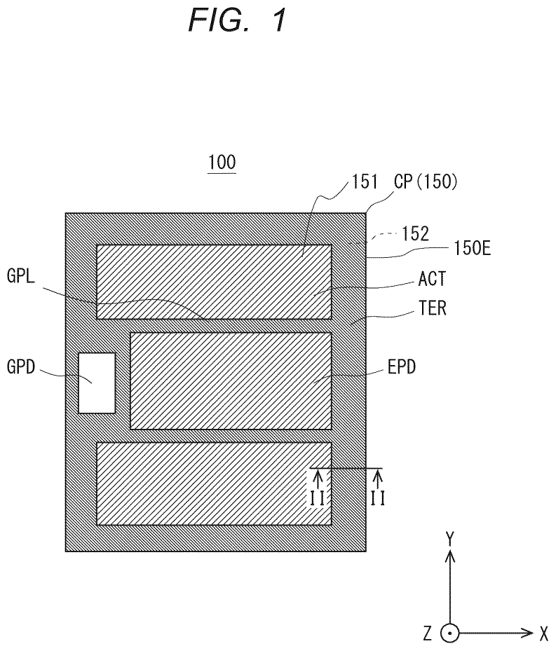

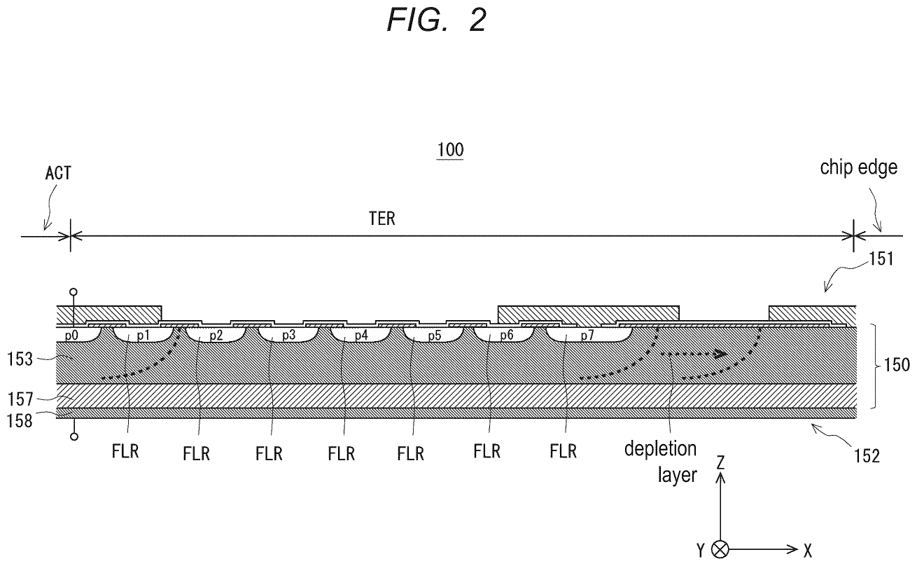

Describing the semiconductor device according to the reference example. FIG. 1 is a plan view illustrating the semiconductor device 100 according to the reference example. FIG. 2 is a cross-sectional view illustrating the semiconductor device 100 according to the reference example, showing the cross-section along line II of FIG. 1. As shown in FIGS. 1 and 2, the semiconductor device 100 of the reference example is formed in the semiconductor chip CP. The semiconductor chip CP includes, for example, a rectangular plate-shaped semiconductor substrate 150. The semiconductor substrate 150 has two plate surfaces and a chip edge 150E. For convenience, the two plate surfaces are referred to as the upper surface 151 and the lower surface 152.

Here, for the convenience of describing the semiconductor device 100 and the like, an XYZ orthogonal coordinate system is introduced. The direction perpendicular to the upper surface 151 is defined as the Z-axis direction, and the two directions orthogonal to the Z-axis direction are defined as the X-axis and Y-axis directions. +Z axis direction is defined as the direction from the lower surface 152 towards the upper surface 151. For convenience, the +Z axis direction is referred to as upward, and the −Z axis direction as downward. Note that upward and downward are directions for the convenience of explanation and do not indicate the actual orientation when using the semiconductor device 100.

The four sides of the rectangular plate-shaped form the chip edge 150E of the semiconductor chip CP. When viewed from the upper surface 151 side, the semiconductor device 100 includes an active region ACT and a termination region TER. The active region ACT is also referred to as the active cell region in the semiconductor device 100 of the reference example. Furthermore, the semiconductor device 100 has a gate pad GPD and an emitter pad EPD on the upper surface 151.

The active region ACT is located in the central portion of the upper surface 151 of the semiconductor chip CP. The active region ACT includes, for example, a plurality of semiconductor devices such as IGBTs. In the active region ACT, a plurality of IGBTs is arranged in a matrix. The gates of the plurality of IGBTs are connected to the gate path line GPL extending from the gate pad GPD. The emitters of the plurality of IGBTs are connected to the emitter pad EPD.

The termination region TER is arranged to surround the active region ACT. The termination region TER is located between the active region ACT and the chip edge 150E.

As shown in FIG. 2, the semiconductor substrate 150 in the termination region TER has a Field Limiting Ring (FLR). Specifically, for example, the semiconductor substrate 150 in the termination region TER includes an N− type drift layer 153 containing an N− epi layer, an N+ type field stop layer 157 containing an N+ substrate, and a P++ type collector layer 158. Furthermore, the semiconductor substrate 150 in the termination region TER has multiple FLRs on the N− type drift layer 153. The FLR includes a P type floating layer. The P type floating layer contains a P type impurity layer. For example, the semiconductor device 100 includes seven FLRs consisting of seven P type floating layers p1 to p7 in the termination region TER. By adding FLRs, the semiconductor device 100 can promote the extension of the depletion layer and maintain high voltage resistance. Thus, in semiconductor devices 100 such as power MOS, FLR structures that can relatively easily achieve high voltage resistance even with shallow junctions are often used.

### Newly Identified Problems by the Inventor

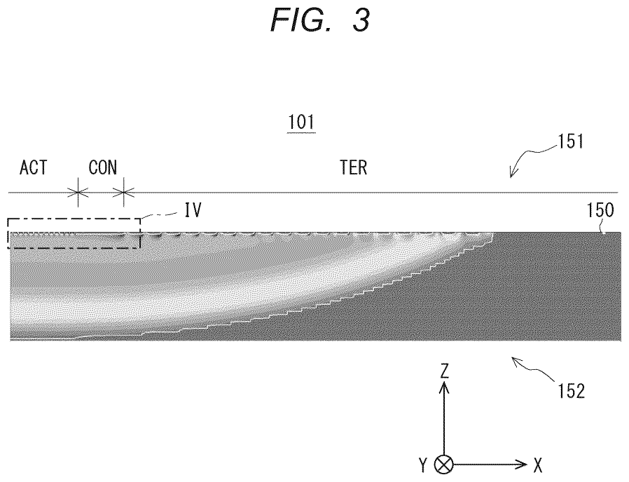

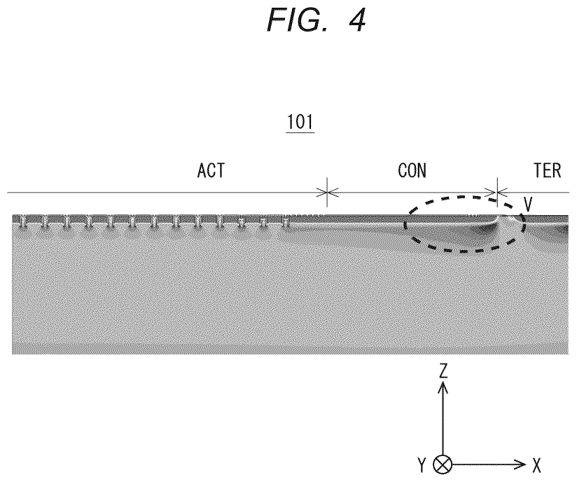

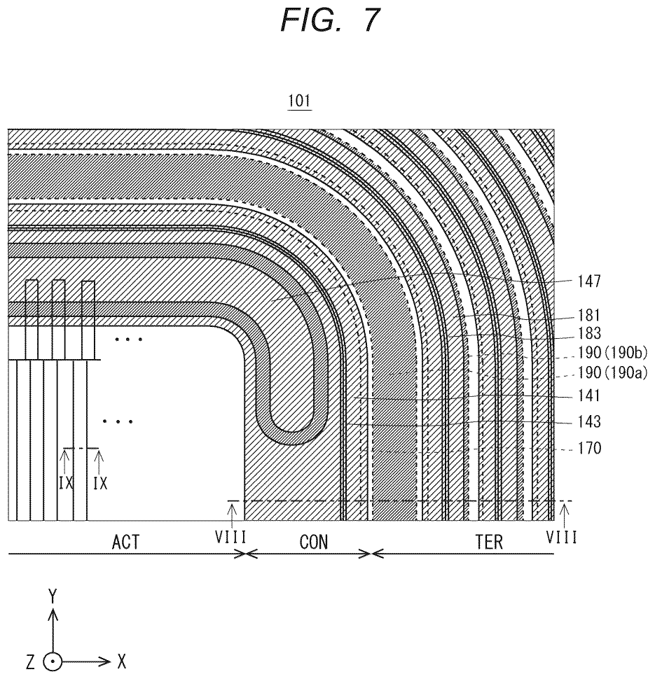

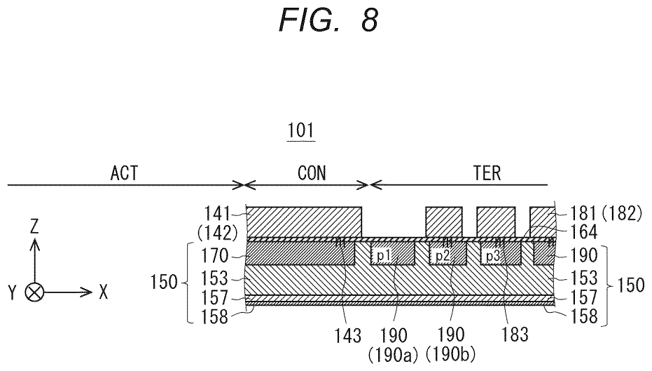

FIG. 3 is a schematic diagram illustrating simulation results of the electric field strength distribution when a reverse bias is applied to the collector in the semiconductor device 101 according to the comparative example. FIG. 4 is a schematic diagram illustrating simulation results of the electric field strength distribution when a reverse bias is applied to the collector in the semiconductor device 101 according to the comparative example, and is an enlarged view of part IV of FIG. 3. As shown in FIGS. 3 and 4, as well as FIGS. 7 and 8 to be described later, when viewed from the top surface side, the semiconductor device 101 according to the comparative example has a semiconductor substrate 150 with an active region ACT, a main junction region CON, and a termination region TER. As will be described later, the main junction region CON is located between the active region ACT and the termination region TER. The main junction region CON has a junction impurity layer connected to the emitter wiring.

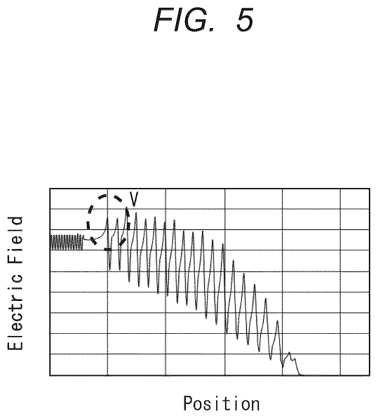

FIG. 5 is a graph illustrating the electric field strength distribution when a reverse bias is applied to the collector in the semiconductor device 101 according to the comparative example, where the horizontal axis indicates the position in the X-axis direction from the active region ACT of the semiconductor device 101 towards the termination region TER, and the vertical axis indicates the electric field strength. As shown in FIGS. 3 to 5, the electric field strength in the semiconductor device 101 according to the comparative example tends to be stronger in the main junction region CON and the termination region TER than in the active region ACT. The parts enclosed by the dotted line V in FIGS. 4 and 5 particularly indicate the regions where the electric field strength becomes high. In cases where there is a path connected to the emitter wiring, such as in the main junction region CON, the incidence of SEB may increase after the incidence of neutron rays in such locations.

Until now, it was believed that SEB occurred only in the active region ACT. However, SEB may also occur in the outermost part of the main junction region CON. This is thought to be because there is a path to the emitter wiring, resulting in a high electric field region. The following embodiments solve at least one of the problems anticipated in the semiconductor device 101 of the comparative example.

### First Embodiment

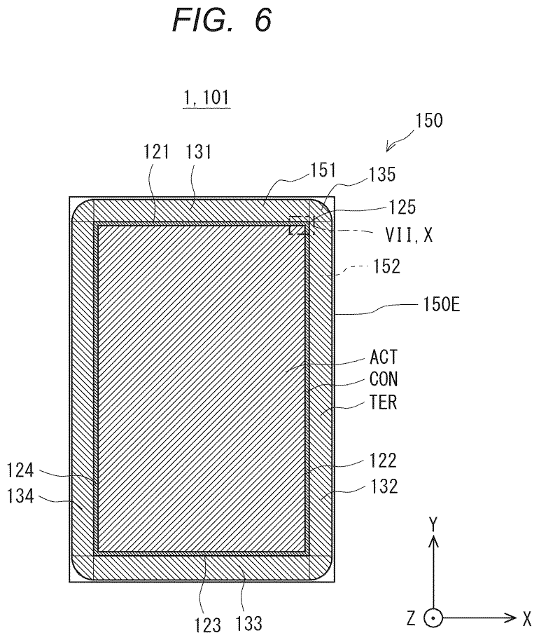

Next, a semiconductor device according to Embodiment 1 will be described. FIG. 6 is a plan view illustrating the semiconductor device 1 according to the first embodiment. As shown in FIG. 6, the semiconductor device 1 of this embodiment includes a semiconductor substrate 150 having an upper surface 151 (first main surface) and a lower surface 152 (second main surface). The upper surface 151 is the surface opposite to the lower surface 152. Note that FIG. 6 is used in place of the description of the semiconductor device 101 of the comparative example.

When viewed from the upper surface 151 side, the semiconductor device 1 has a semiconductor substrate 150 with an active region ACT, a main junction region CON, and a termination region TER. The active region ACT includes multiple semiconductor elements such as IGBTs formed on the semiconductor substrate 150. The main junction region CON is located between the active region ACT and the termination region TER. The main bonding region CON is arranged to surround the active region ACT. The termination region TER is arranged to surround both the active region ACT and the main bonding region CON.

The main bonding region CON is, broadly speaking, in the shape of a rectangular frame. Note that the shape of the main bonding region CON is not limited to a rectangular frame and may be changed according to the outer shape of the semiconductor device 1. Hereinafter, the shape of the main bonding region CON will be described as a rectangular frame. When viewed from the top surface 151 side, the main bonding region CON includes regions 121, 122, 123, and 124.

Region 121 is the portion on the +Y axis side of the active region ACT. Region 121 extends in the X-axis direction. Region 121 is located between the +Y axis side end of the active region ACT in the Y-axis direction and the termination region TER. Region 121 separates the active region ACT and the termination region TER in the Y-axis direction. Region 122 is the portion on the +X axis side of the active region ACT. Region 122 extends in the Y-axis direction. Region 122 is located between the +X axis side end of the active region ACT in the X-axis direction and the termination region TER. Region 122 separates the active region ACT and the termination region TER in the X-axis direction.

Region 123 is the portion on the −Y axis side of the active region ACT. Region 123 extends in the X-axis direction. Region 123 is located between the −Y axis side end of the active region ACT in the Y-axis direction and the termination region TER. Region 123 separates the active region ACT and the termination region TER in the Y-axis direction. Region 124 is the portion on the −X axis side of the active region ACT. Region 124 extends in the Y-axis direction. Region 124 is located between the −X axis side end of the active region ACT in the X-axis direction and the termination region TER. Region 124 separates the active region ACT and the termination region TER in the X-axis direction. Regions 121 and 123, which extend in the X-axis direction, are called the first main bonding portions, and regions 122 and 124, which extend in the Y-axis direction, are called the second main bonding portions.

Furthermore, the main bonding region CON includes corner portion 125 (the third main bonding portion). Corner portion 125 includes the connection portion where region 121 and region 122 are connected, the connection portion where region 122 and region 123 are connected, the connection portion where region 123 and region 124 are connected, and the connection portion where region 124 and region 121 are connected. Corner portion 125 may appropriately be provided with a rounded shape having a radius R.

The termination region TER is in the shape of a rectangular frame. Note that the shape of the termination region TER is not limited to a rectangular frame and may be changed according to the outer shape of the semiconductor device 1 and the main bonding region CON, etc. Hereinafter, the shape of the termination region TER will be described as a rectangular frame. When viewed from the top surface 151 side, the termination region TER includes regions 131, 132, 133, and 134.

Region 131 is the part on the +Y axis side more than region 121. Region 131 extends in the X-axis direction. Region 131 is sandwiched between the active region ACT in the Y-axis direction. Region 132 is a part on the +X axis side relative to region 122. Region 132 extends in the Y-axis direction. In the X-axis direction, region 132 is located between the active region ACT and region 122.

Region 133 is a part on the −Y axis side relative to region 123. Region 133 extends in the X-axis direction. In the Y-axis direction, region 133 is located between the active region ACT and region 123. Region 134 is a part on the −X axis side relative to region 124. Region 134 extends in the Y-axis direction. In the X-axis direction, region 134 is located between the active region ACT and region 124. Regions 131 and 133, which extend in the X-axis direction, are called the first termination portion, and regions 132 and 134, which extend in the Y-axis direction, are called the second termination portion.

Furthermore, the termination region TER includes a corner portion 135 (the third termination portion). Corner portion 135 includes the connection portion where region 131 and region 132 are connected, the connection portion where region 132 and region 133 are connected, the connection portion where region 133 and region 134 are connected, and the connection portion where region 134 and region 131 are connected. Corner portion 135 may be provided with a rounded shape having a radius R as appropriate.

In this embodiment, the semiconductor device 1 has the main bonding region CON arranged in connection with the termination region TER in the region surrounding the active region ACT.

Next, the configuration of the semiconductor device 1 according to this embodiment will be explained in comparison with the configuration of the semiconductor device 101 according to the comparative example. Therefore, first, the configuration of the semiconductor device 101 according to the comparative example will be explained.

### Semiconductor Device of Comparative Example

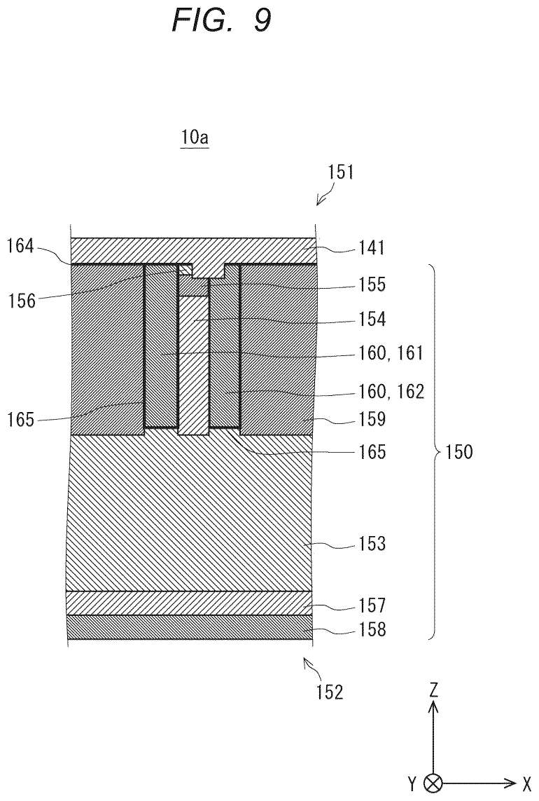

FIG. 7 is a plan view illustrating the semiconductor device 101 according to the comparative example, showing an enlarged view of the part VII of FIG. 6. FIG. 8 is a cross-sectional view illustrating a main junction region CON and a termination region TER of the semiconductor device 101 according to the comparative example, showing the cross-section along the line VIII-VIII of FIG. 7. FIG. 9 is a cross-sectional view illustrating the IGBT 10a in an active region ACT of the semiconductor device 101 according to the comparative example, showing the cross-section along the line IX-IX of FIG. 7.

As shown in FIGS. 7 to 9, the semiconductor device 101 of the comparative example has the active region ACT, the main junction region CON, and the termination region when viewed from above. The semiconductor device 101 includes an emitter wiring 141, gate wiring 147, and termination wiring 181 provided on the upper surface 151 of the semiconductor substrate 150 via an insulating film 164. The emitter wiring 141, gate wiring 147, and termination wiring 181 may be aluminum wiring including aluminum (Al).

### Active Region

In the semiconductor substrate 150 of the active region ACT, for example, multiple IGBT 10a are formed. In the active region ACT of FIG. 7, the gate trench electrodes 160 of multiple IGBT 10a are schematically simplified and shown. As shown in FIG. 9, for example, IGBT 10a has an N− type drift layer 153, an N+ type barrier layer 154, a P type channel layer 155, an N+ type emitter layer 156, a gate trench electrode 160, a gate trench insulating film 165, an N+ type field stop layer 157, a P++ type collector layer 158, and a P type floating layer 159. Note that IGBT 10a may include additional members in addition to these members, or some of these members may be omitted. To avoid cluttering the figure, the gate trench insulating film 165 and the insulating film 164 on the semiconductor substrate 150 are shown with thick lines. The P type floating layer 159 may be referred to as the IGBT floating layer.

Note that N++ type and P++ type indicate low-resistance N type and P type conductivity, respectively. N+ type and P+ type are higher resistance than N++ type and P++ type, respectively, but indicate lower resistance N type and P type conductivity than N type and P type. P− type and N− type indicate that they are higher resistance N type and P type conductivity than N type and P type, respectively. Therefore, N type and P type indicate that they are N type and P type conductivity with resistance between N+ type and P+ type and P− type and N− type, respectively. N+ type and P+ type indicate that they are N type and P type conductivity with resistance between N++ type and P++ type and P type and N type, respectively. Hereinafter, unless specifically mentioned, the same meaning is implied. N type conductivity may be referred to as the first conductivity type, and P type conductivity may be referred to as the second conductivity type.

Note that N type conductivity may be considered as the second conductivity type, and P type conductivity as the first conductivity type. Furthermore, semiconductor devices with the conductivity types of each component reversed from those disclosed herein are also within the scope of the technical ideas of this disclosure. Moreover, the resistances of the N++ type, N+ type, N type, and N− type semiconductor layers are examples. The resistance may be greater than that shown in this disclosure, or it may be smaller. Similarly, the resistances of the P++ type, P+ type, P type, and P− type semiconductor layers are examples. The relative resistance of each semiconductor layer may be reversed depending on the case.

The N− type drift layer 153 is provided on the surface 151 side above the N+ type field stop layer 157. The N− type drift layer 153 is provided across the active region ACT, the main junction region CON, and the termination region TER.

The N+ type barrier layer 154 is provided on the surface 151 side above the N− type drift layer 153. The N+ type barrier layer 154 extends in the Y-axis direction, for example, when viewed from the surface 151 side. The N+ type barrier layer 154 is sandwiched by gate trench electrodes 160 on both sides in the X-axis direction. That is, the N+ type barrier layer 154 is located inside, sandwiched by the gate trench electrodes 160.

The P type channel layer 155 is provided on the surface 151 side above the N+ type barrier layer 154. The P type channel layer 155 is sandwiched by gate trench electrodes 160 on both sides in the X-axis direction. The P type channel layer 155 connects to the emitter wiring 141 filled in the through-hole that penetrates the insulating film 164 and the N+ type emitter layer 156.

The N+ type emitter layer 156 is provided on the surface 151 side above the P type channel layer 155. The N+ type emitter layer 156 is located inside, surrounded by the gate trench electrodes 160. The N+ type emitter layer 156 connects to the emitter wiring 141 filled in the through-hole that penetrates the insulating film 164.

A pair of gate trench electrodes 160 are provided to sandwich the N+ type barrier layer 154, the P type channel layer 155, and the N+ type emitter layer 156 from both sides in the X-axis direction. Each gate trench electrode 160 includes a portion that extends in the Y-axis direction, for example, when viewed from the surface 151 side. For example, among a pair of gate trench electrodes 160, the one on the −X axis side is called gate trench electrode 161, and the one on the +X axis side is called gate trench electrode 162. Therefore, the pair of gate trench electrodes 160 of IGBT 10a includes gate trench electrode 161 and gate trench electrode 162.

Gate trench electrode 161 connects to the gate wiring 147, for example. Gate trench electrode 162 connects to the emitter wiring 141 filled in the through-hole that penetrates the insulating film 164. Therefore, the N+ type emitter layer 156, the P type channel layer 155, and gate trench electrode 162 connect to the emitter wiring 141. The structure between a pair of gate trench electrodes 160 is called the trench structure. For example, the trench structure of IGBT 10a includes the N+ type barrier layer 154, the P type channel layer 155, and the N+ type emitter layer 156. The trench structure of IGBT 10a may include other components such as contact layers.

The P type floating layer 159 is provided between adjacent IGBT 10a in multiple IGBT 10a. For example, the P type floating layer 159 is provided between the gate trench electrode 162 of the IGBT 10a on the −X axis side and the gate trench electrode 161 of the IGBT 10a on the +X axis side among adjacent IGBT 10a. The P type floating layer 159 is provided on the opposite side of the N+ type barrier layer 154, the P type channel layer 155, and the N+ type emitter layer 156, across the gate trench electrodes 160.

The P type floating layer 159 is provided on the surface 151 side above the N− type drift layer 153. Therefore, on the N− type drift layer 153, from the −X axis direction side, along the X axis direction, the P type floating layer 159, gate trench electrode 161 (covered with gate trench insulating film 165), trench structure, gate trench electrode 162 (covered with gate trench insulating film 165), and the P type floating layer 159 are arranged. In the active region ACT, such a configuration is arranged to repeat in the X-axis direction.

The P type floating layer 159 at the +X axis direction end in the X-axis direction of the active region ACT and the P type floating layer 159 between the P type floating layer 159 at the −X axis direction end in the X-axis direction of the active region ACT are in contact with the gate trench electrodes 161 and 162. In other words, except for the ends in the X-axis direction of the active region ACT, the P type floating layer 159 is formed between adjacent IGBT 10a.

The gate trench insulating film 165 is provided between the gate trench electrode 160 and the semiconductor substrate 150. Specifically, the gate trench insulating film 165 is provided between the gate trench electrode 160 and the N− type drift layer 153, N+ type barrier layer 154, P-type channel layer 155, N+ type emitter layer 156, and P type floating layer 159.

The N+ type field stop layer 157 is provided on the surface 152 side below the N− type drift layer 153. The P++ type collector layer 158 is provided on the surface 152 side below the N+ type field stop layer 157. The P++ type collector layer 158 is connected to the collector wiring. Note that the collector wiring is omitted so as not to complicate the figure.

### Main Junction Region

The semiconductor substrate 150 of the main junction region CON has an N− type drift layer 153, an N+ type field stop layer 157, a P++ type collector layer 158, and a P type junction impurity layer 170. Furthermore, the semiconductor substrate 150 of the main junction region CON may include other members in addition to these members, or some of these members may be omitted. The P type junction impurity layer 170 is provided on the surface 151 side above the N− type drift layer 153. The N+ type field stop layer 157 is provided on the surface 152 side below the N− type drift layer 153. The P++ type collector layer 158 is provided on the surface 152 side below the N+ type field stop layer 157.

The P type junction impurity layer 170 is connected to the emitter wiring 141 in the main junction region CON. The emitter wiring 141 has, for example, a main body portion 142 and a contact 143. The contact 143 is the portion that connects to the P type junction impurity layer 170 in the emitter wiring 141. The P type junction impurity layer 170 is connected to the emitter wiring 141 through the contact 143. Note that the contact 143 in FIGS. 7 and 8 is composed of three portions, but it is not limited to this and may be composed of one portion or multiple portions other than three.

### Termination Region

The semiconductor substrate 150 in the termination region TER has an N− type drift layer 153, an N+ type field stop layer 157, a P++ type collector layer 158, and multiple P type floating layers 190. The multiple P type floating layers 190 are provided on the upper surface 151 side, above the N− type drift layer 153. The N+ type field stop layer 157 is provided on the lower surface 152 side, below the N− type drift layer 153. The P++ type collector layer 158 is provided on the lower surface 152 side, below the N+ type field stop layer 157. The multiple P type floating layers 190 form an FLR.

The P type floating layer 190 is connected to the termination wiring 181 in the termination region TER. The termination wiring 181 has, for example, a main body 182 and a contact 183. The contact 183 is the portion that connects to the P type floating layer 190 in the termination wiring 181. The P type floating layer 190 is connected to the termination wiring 181 via the contact 183.

The P type floating layer 190a closest to the main junction region CON in the termination region TER is called the first ring layer p1. The second P type floating layer 190b from the main junction region CON side in the termination region TER is called as a second ring layer p2. Similarly, the k-th P type floating layer 190 from the main junction region CON side in the termination region TER is called as k-th ring layer pk.

The termination wiring 181 is not formed on the first ring layer p1, that is, on the P type floating layer 190a. Therefore, the P type floating layer 190a constituting the first ring layer p1 is not connected to the termination wiring 181. On the other hand, the termination wiring 181 is formed on the second ring layer p2 (P type floating layer 190b), the third ring layer p3, and the k-th ring layer pk. The P type floating layers 190 other than the P type floating layer 190a are connected to the termination wiring 181 via the contact 183.

The termination wiring 181 is not connected to the emitter wiring 141 and is in a floating state. Therefore, the P type floating layers 190 constituting the FLR are in a floating state. Thus, the P type floating layers 190 are not connected to the emitter wiring 141 in the termination region TER.

### Semiconductor Device of First Embodiment

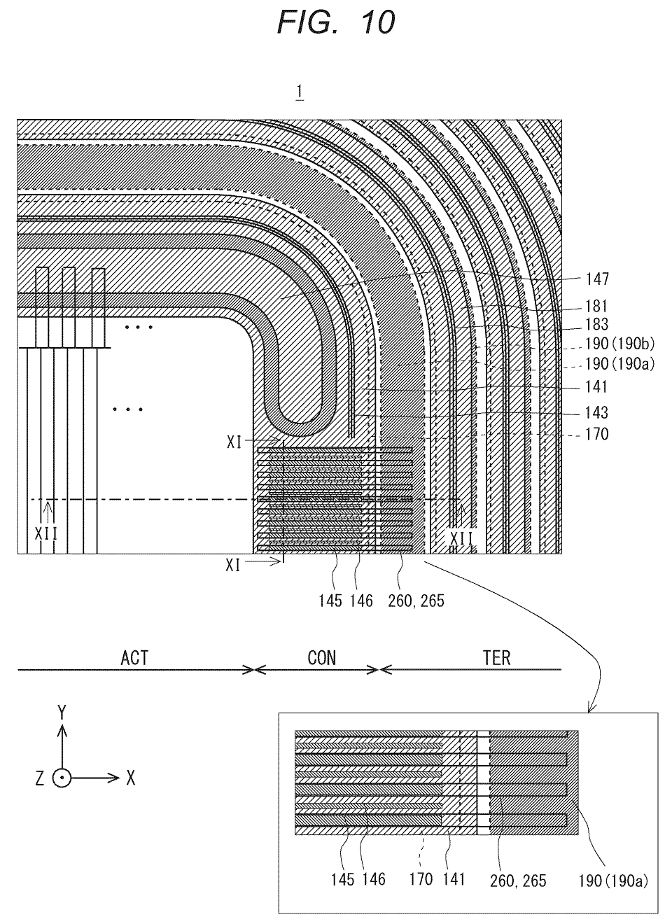

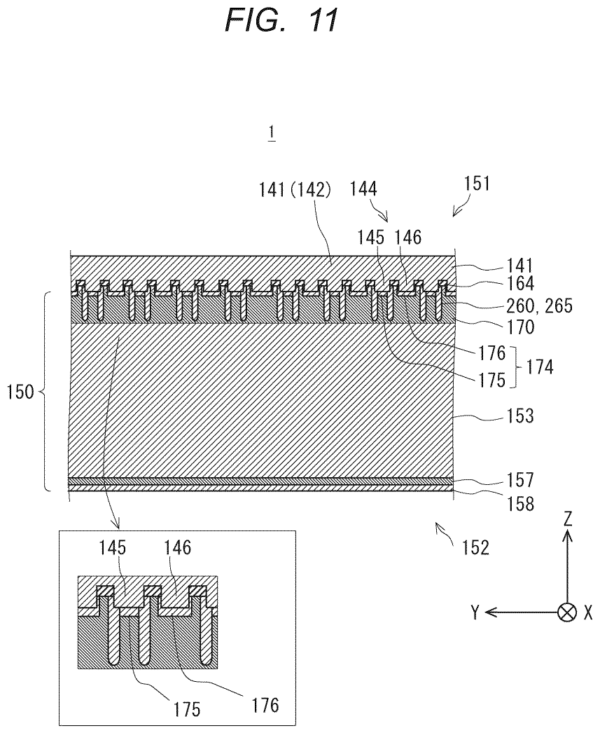

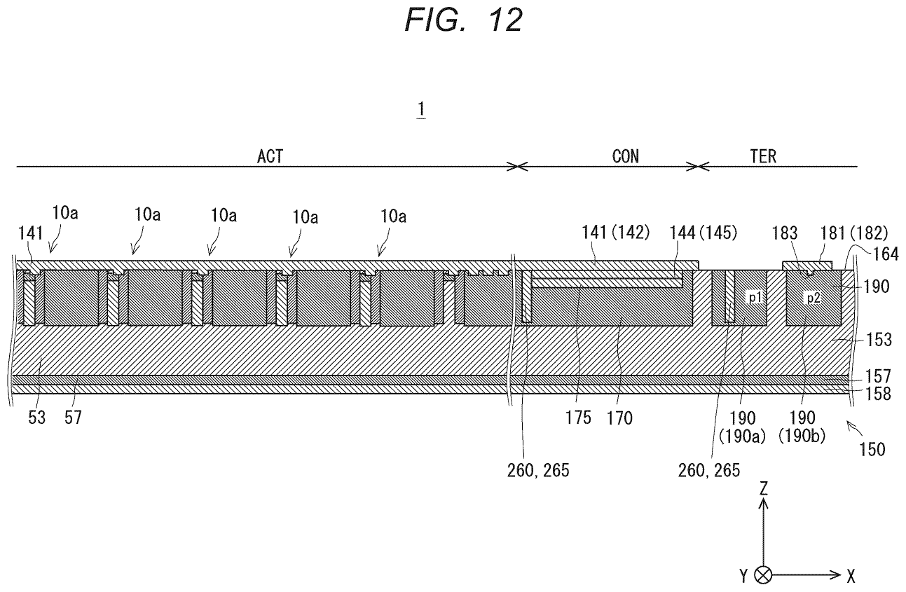

Next, the semiconductor device of first embodiment will be described. FIG. 10 is a plan view illustrating the semiconductor device 1 according to first embodiment, and is an enlarged view illustrating the X portion of FIG. 6. FIG. 11 is a cross-sectional view illustrating the semiconductor device 1 according to first embodiment, showing the cross-section along line XI-XI of FIG. 10. FIG. 12 is a cross-sectional view illustrating the semiconductor device 1 according to first embodiment, showing the cross-section along line XII-XII of FIG. 10. FIGS. 10 and 11 also show an enlarged view of a part of the main junction region CON.

As shown in FIG. 10, the semiconductor device 1 of this embodiment has an active region ACT, a main junction region CON, and a termination region when viewed from above, similar to the comparative example semiconductor device 101. In the semiconductor device 1 of this embodiment, at least the main bonding region CON of the semiconductor substrate 150 has a trench electrode 260 and a trench insulating film 265. In FIG. 10, to avoid complicating the drawing, the trench electrode 260 and the trench insulating film 265 are indicated by lines. A single line indicates both the trench electrode 260 and the trench insulating film 265. Therefore, in the figure, the trench electrode 260 is rectangular in shape. That is, when viewed from the top surface 151 side, the trench electrode 260, for example, is annular with both ends of two portions extending in the X-axis direction connected.

In the figure, the trench electrode 260 is formed in the regions 122 and 132 on the +X axis side of the active region ACT, but it may also be formed in the regions 124 and 134 on the −X axis side of the active region ACT.

### Trench Electrode

As shown in FIGS. 10 to 12, the trench electrode 260 is provided inside a trench formed on the top surface 151 of the semiconductor substrate 150. The trench insulating film 265 is provided between the trench electrode 260 and the semiconductor substrate 150. When viewed from the top surface 151 side, the trench electrode 260 includes a portion extending in the X-axis direction from the main bonding region CON towards the termination region TER. Specifically, one end of the trench electrode 260 in the X-axis direction is located in the main bonding region CON, and the other end is located in the termination region TER. For example, the end of the trench electrode 260 on the −X axis side is located in the P type junction impurity layer 170 of the main bonding region CON, and the end on the +X axis side is located in the P type floating layer 190a of the termination region TER. The cross-sectional shapes of the trench electrode 260 in FIGS. 11 and 12 are both schematic diagrams.

The termination region TER has multiple P type floating layers 190 including portions extending in the Y-axis direction. As mentioned earlier, among the multiple P type floating layers 190 in the termination region TER, the one closest to the main bonding region CON is considered as a first P type floating layer. The P type floating layer 190b adjacent to the first P type floating layer is considered as a second P type floating layer. In this case, the end of the trench electrode 260 on the termination region TER side is located in the first P type floating layer (190a).

As shown in FIGS. 11 and 12, the lower end of the trench electrode 260, that is, the end on the −Z axis side, is located in the P type junction impurity layer 170 and the P type floating layer 190a. The lower end of the trench electrode 260 may also be located in the N− type drift layer 153.

The trench electrode 260 is connected to the emitter wiring 141 in the main bonding region CON. The emitter wiring 141 further has a contact 144. The contact 144 may include a first contact 145 and a second contact 146. The contact 144 may be referred to as the emitter contact. The first contact 145 and the second contact 146 may be referred to as the first emitter contact and the second emitter contact, respectively. The first contact 145 connects to the P type junction impurity layer 170 and the trench electrode 260 within the annular trench electrode 260. The second contact 146 connects to the P type junction impurity layer 170 between the annular trench electrodes 260 adjacent in the Y-axis direction.

The first contact 145 and the second contact 146 are formed within the range of the main junction region CON. The first contact 145 and the second contact 146 are not formed in the P-type floating layer 190a in the termination region TER.

The semiconductor substrate 150 of the main junction region CON may have a P type contact layer 174 provided on the surface 151 side above the P type junction impurity layer 170. The P type contact layer 174 contains a higher concentration of P type impurities than the P type junction impurity layer 170. The P type contact layer 174 may include the first contact layer 175 and the second contact layer 176. The P type contact layer 174 may be referred to as an emitter contact layer. The first contact layer 175 and the second contact layer 176 may be referred to as a first emitter contact layer and a second emitter contact layer, respectively.

The first contact layer 175 is located inside the annular trench electrode 260. The second contact layer 176 is located between the annular trench electrodes 260 adjacent in the Y-axis direction. The first contact 145 is connected to the P type junction impurity layer 170 via the first contact layer 175. The second contact 146 is connected to the P type junction impurity layer 170 via the second contact layer 176. The upper end of the trench electrode 260 on the +Z axis side has a step relative to the lower end of the first contact 145 on the −Z axis side. The trench electrode 260 is connected to the emitter wiring through the step. Thus, the trench electrode 260 can increase the contact region with the emitter wiring 141.

The contact 144 connects to the P type junction impurity layer 170 as well as to the trench electrode 260. Thus, the trench electrode 260 connects to the emitter wiring 141. In this way, the semiconductor device 1 of this embodiment has a trench electrode 260 of emitter potential connected to the emitter wiring 141 at least in the main junction region CON. The semiconductor device 1 has a contact 144 for fixing the trench electrode 260 to the emitter potential. Furthermore, the semiconductor device 1 has a contact 144 for enhancing hole discharge during turn-off. Thus, the semiconductor device 1 can suppress the occurrence of SEB due to electric field relaxation by forming the contact 144 connecting to the emitter wiring 141. This can improve cosmic ray resistance as well as collector withstand voltage and hole discharge effect. Thus, the semiconductor device 1 can suppress current concentration and improve destruction resistance (Reverse Bias Safe Operating Area, hereinafter referred to as RBSOA).

### First Modification Example

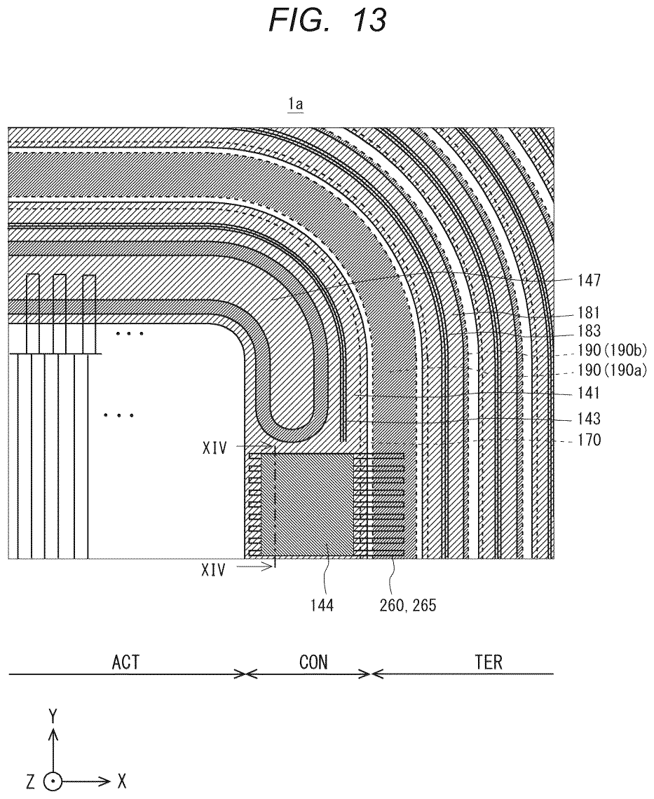

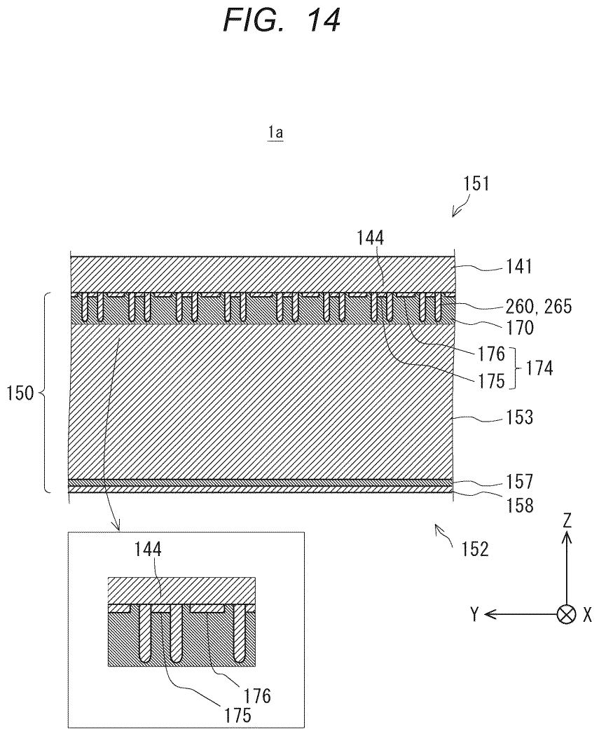

FIG. 13 is a plan view illustrating a semiconductor device 1a according to First Modification Example of first embodiment. FIG. 14 is a cross-sectional view illustrating the semiconductor device 1a according to First Modification Example of first embodiment, showing the cross-section along line XIV-XIV of FIG. 13. FIG. 14 also shows an enlarged view of a part of the main junction region CON.

As shown in FIGS. 13 and 14, in the semiconductor device 1a according to the first modification, the contact 144 is formed across multiple annular trench electrodes 260 and P type junction impurity layers 170 arranged in the Y-axis direction. The upper end of the trench electrode 260 is formed flat to align with the upper surface 151 of the semiconductor substrate 150. Thus, the contact 144 is connected to the P type junction impurity layer 170 via the first contact layer 175 and the second contact layer 176. The upper end on the +Z axis side of the trench electrode 260 is connected to the lower end of the contact 144. By arranging the contact 144 formed across the multiple annular trench electrodes 260 and P type junction impurity layers 170, it is possible to increase the contact region and simplify the manufacturing process.

### Second Modification

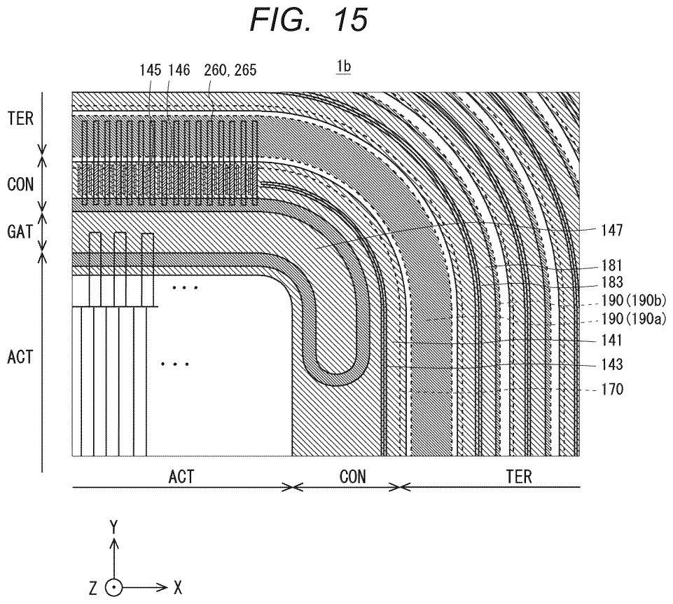

FIG. 15 is a plan view illustrating a semiconductor device 1b according to the second modification of first Embodiment. As shown in FIG. 15, in the semiconductor device 1b of Second Modification, the trench electrode 260 is formed in regions 121 and 131 located on the +Y axis side more than the active region ACT. The trench electrode 260 includes a portion extending in the Y-axis direction from the active region ACT towards the termination region TER. It should be noted that the trench electrode 260 may be formed in regions 123 and 133 located on the −Y axis side more than the active region ACT.

In this modification as well, when viewed from the upper surface 151 side, the trench electrode 260 includes a portion extending in the direction from the main junction region CON towards the termination region TER, but the trench electrode 260 extends in the Y-axis direction. Specifically, one end of the trench electrode 260 in the Y-axis direction is located in the main junction region CON, and the other end is located in the termination region TER. For example, the end on the −Y axis side of the trench electrode 260 is located in the P type junction impurity layer 170 of the main junction region CON, and the end on the +Y axis side of the trench electrode 260 is located in the P type floating layer 190a of the termination region TER.

In region 131, the termination region TER has multiple P type floating layers 190 including portions extending in the X-axis direction. Among the multiple P type floating layers 190 in the termination region TER, the P type floating layer 190a closest to the main junction region CON is considered as a first P type floating layer. When the P type floating layer 190b next to the first P type floating layer is considered as a second P type floating layer, the end of the trench electrode 260 on the termination region TER side is located in the first P type floating layer.

When viewed from the upper surface 151 side, the semiconductor substrate 150 has a gate wiring region GAT arranged between the main junction region CON and the active region ACT in the Y-axis direction. The gate wiring region GAT has gate wiring 147 arranged on the upper surface 151 of the semiconductor substrate 150 via an insulating film 164. The gate trench electrode 161 of the IGBT 10a is connected to the gate wiring 147 in the gate wiring region GAT.

The trench electrode 260, if at least located in the main junction region CON, may extend to the gate wiring region GAT in the Y-axis direction, or may extend to the termination region TER. Furthermore, the trench electrode 260 may be arranged only in the main bonding region CON.

In the semiconductor device 1b of Second Modification Example, the contact 144 of the emitter wiring 141 may have a first contact 145 and a second contact 146. Furthermore, the contact 144 may be connected to multiple annular trench electrodes 260 and P type junction impurity layers 170.

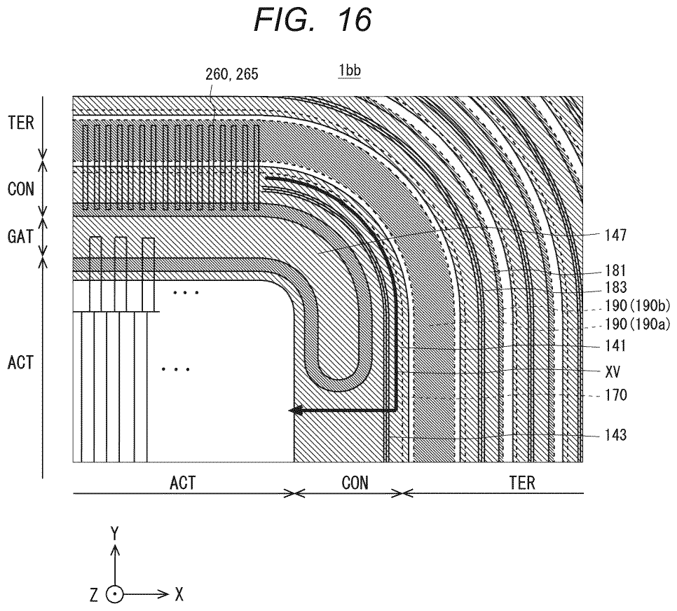

FIG. 16 is a plan view illustrating a semiconductor device 1bb according to another example of Second Modification Example of first embodiment. As shown in FIG. 16, the semiconductor device 1bb may not include the contact 144. Since the semiconductor device 1bb has a gate wiring 147, current flows through a path as indicated by arrow XV in the figure. Due to such current, if there is an effect of potential fluctuation, it may be permissible to reduce the contact 144 of the emitter wiring 141. Although the carrier extraction effect is reduced, the dynamic avalanche is suppressed by the electric field relaxation effect. Therefore, compared with the semiconductor device 101 of the comparative example, the RBSOA resistance can be improved.

### Third Modification Example

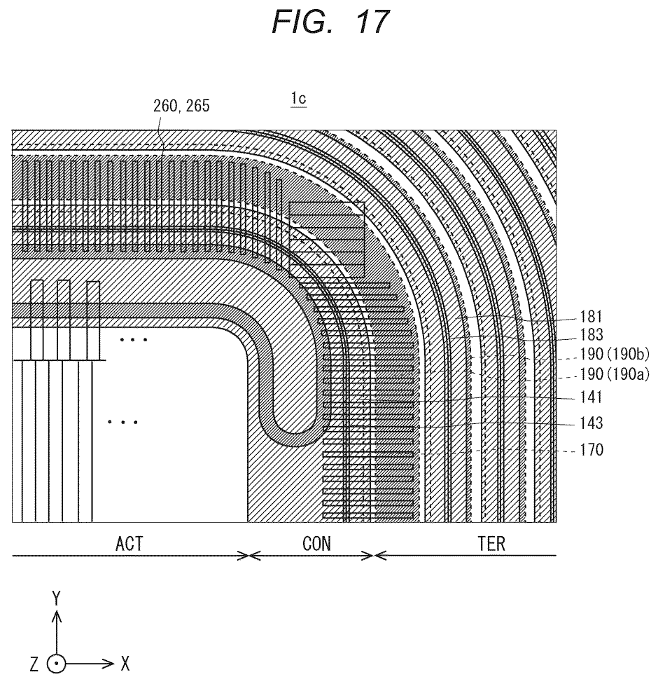

FIG. 17 is a plan view illustrating a semiconductor device 1c according to Third Modification Example of first embodiment. As shown in FIG. 17, in the semiconductor device 1c of Modification Example 3, the trench electrode 260 is formed at the corner portion 125. The trench electrode 260 includes a portion extending in the X-axis direction or the Y-axis direction at the corner portion 125. The trench electrode 260 may include a portion extending from the corner portion 125 to the corner portion 135. Furthermore, the trench electrode 260 may include a portion extending from the corner portion 125 to the gate wiring region GAT. By placing the trench electrode 260 at the corner portion 125, it is possible to relax the electric field at the corner portion 125 and the like of the semiconductor device 1c.

When there is a possibility of affecting the shape of the FLR in the termination region TER, it is desirable to optimize the structure of the trench electrode 260 and the FLR. Furthermore, the trench electrode 260 is not limited to a shape including a portion extending in the X-axis direction or the Y-axis direction, but may be curved to match the shape of the FLR.

Next, the effects of this embodiment will be explained. In the semiconductor devices 1, 1a, 1b, 1bb, and 1c of this embodiment (hereinafter referred to as semiconductor device 1), the trench electrode 260 and the P type junction impurity layer 170 in the main junction region CON are connected to the emitter wiring 141. As a result, the semiconductor device 1 can form a hole discharge path in the main junction region CON and improve the hole discharge effect. Therefore, it is possible to suppress local current concentration and improve RBSOA resistance. The semiconductor device 1 of this embodiment has an electric field relaxation effect in the highest electric field region shown in FIGS. 3 to 5, for example. This allows for an improvement in withstand voltage due to the relaxation effect on the critical electric field.

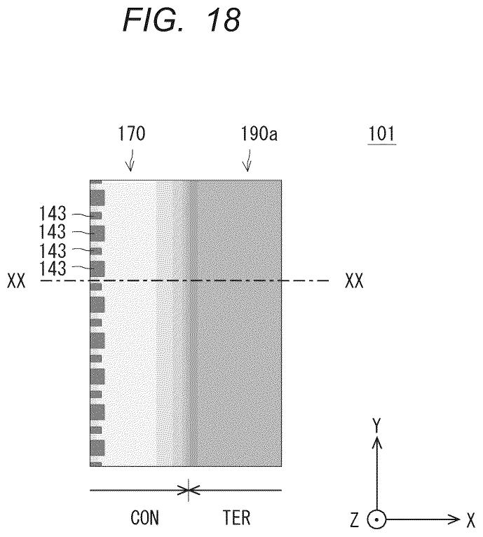

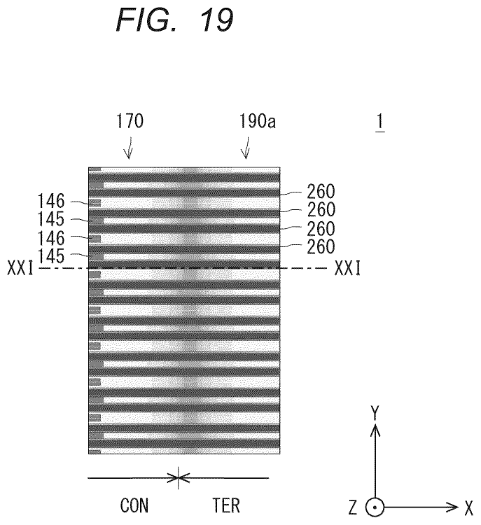

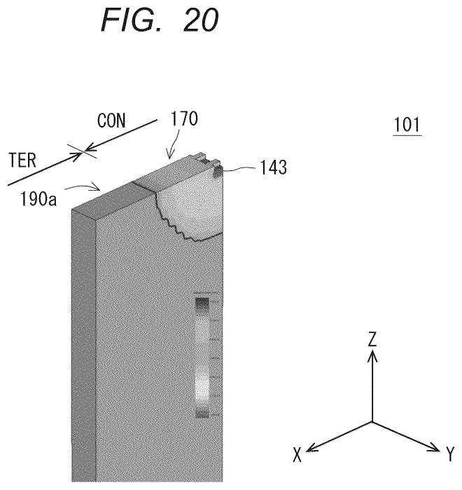

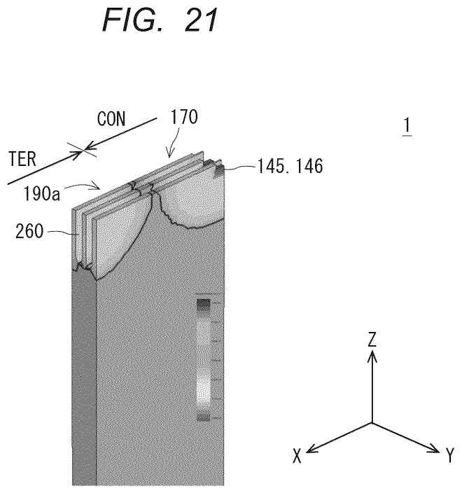

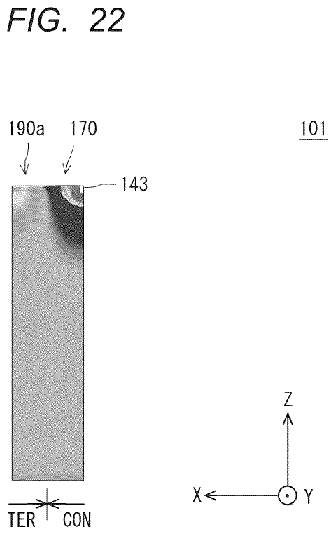

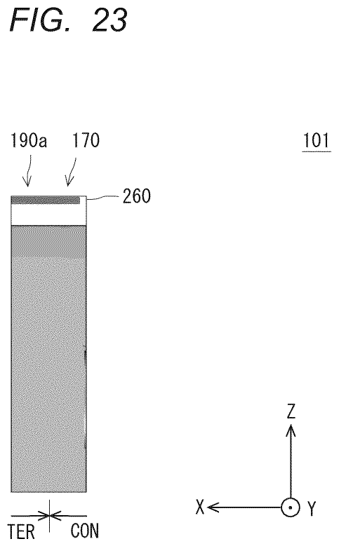

FIGS. 18 and 19 are plan views illustrating simulation results of electric field strength distribution at the boundary between the main junction region CON and the termination region TER in the semiconductor device 101 according to the comparative example and the semiconductor device 1 according to first embodiment, respectively. FIGS. 20 and 21 are perspective views illustrating simulation results of electric field strength distribution at the boundary between the main junction region CON and the termination region TER in the semiconductor device 101 according to the comparative example and the semiconductor device 1 according to first embodiment, respectively, showing the cross-sectional perspective views along line XX-XX of FIG. 18 and line XXI-XXI of FIG. 19. FIGS. 22 and 23 are cross-sectional views illustrating simulation results of electric field strength distribution at the boundary between the main junction region CON and the termination region TER in the semiconductor device 101 according to the comparative example and the semiconductor device 1 according to Embodiment 1, respectively.

As shown in FIGS. 18, 20, and 22, the multiple contact grooves connected to the contact 143 of the emitter wiring 141 in the P-type junction impurity layer 170 of the main junction region CON of the semiconductor device 101 according to the comparative example are in a high electric field region. On the other hand, as shown in FIGS. 19, 21, and 23, the semiconductor device 1 according to this embodiment has, in addition to the multiple contact grooves connected to the contact 144 of the emitter wiring 141 in the P-type junction impurity layer 170 of the main junction region CON, a trench electrode 260 connected to the emitter wiring 141. This allows for the relaxation of the electric field in the P type junction impurity layer 170 of the main junction region CON.

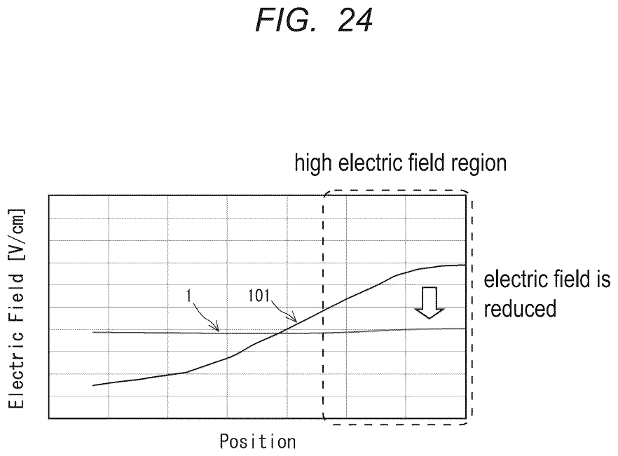

FIG. 24 is a graph illustrating the electric field strength distribution of the semiconductor device 101 according to the comparative example and the semiconductor device 1 according to Embodiment 1, where the horizontal axis indicates the position at the boundary between the main junction region CON and the termination region TER, and the vertical axis indicates the electric field strength. As shown in FIG. 24, in the semiconductor device 101 of the comparative example, the electric field strength in the main junction region CON is much higher than that in the termination region TER.

In contrast, in the semiconductor device 101 according to first embodiment, the electric field strength in the main junction region CON is reduced compared to the comparative example, and the electric field strength in the termination region TER is higher than in the comparative example. Thus, the difference in electric field strength between the main junction region CON and the termination region TER in the semiconductor device 1 of first embodiment is reduced. Thus, the semiconductor device 1 of first embodiment can alleviate the electric field concentration in the main junction region CON.

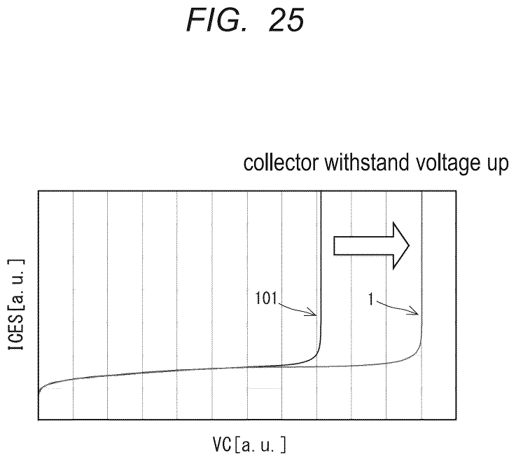

FIG. 25 is a graph illustrating the collector breakdown voltage of the semiconductor device 101 according to the comparative example and the semiconductor device 1 according to first embodiment, where the horizontal axis indicates the collector voltage VC, and the vertical axis indicates the leak current ICES. As shown in FIG. 25, the collector breakdown voltage of the semiconductor device 1 of first embodiment can be significantly improved compared to the semiconductor device 101 of the comparative example.

In the semiconductor device 1 of this embodiment, the electric field relaxation structure is due to the trench electrode 260 at the emitter potential. Therefore, even if hot carriers are generated, it does not affect the variation in characteristics with respect to the trench electrode 260 at the emitter potential.

### Second Embodiment

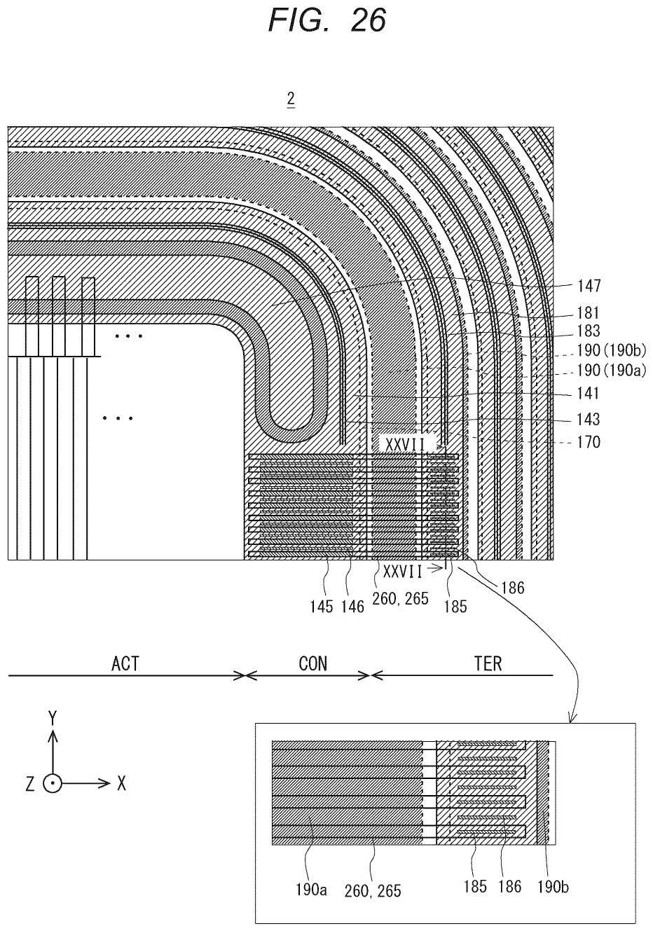

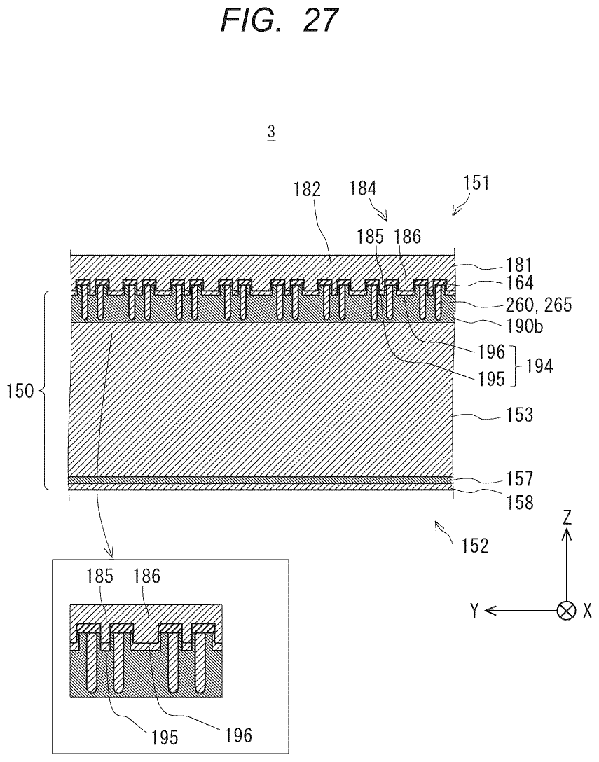

Next, a semiconductor device according to second embodiment will be described. FIG. 26 is a plan view illustrating a semiconductor device 2 according to second embodiment. FIG. 27 is a cross-sectional view illustrating the semiconductor device 2 according to second embodiment, showing the cross-section along line XXVII-XXVII in FIG. 26. FIGS. 26 and 27 also show an enlarged view of a part of the termination region TER. As shown in FIGS. 26 and 27, in the semiconductor device 2, the end of the trench electrode 260 on the termination region TER side is located in the second P type floating layer 190b from the main junction region CON side.

The P type floating layer 190b is connected to the termination wiring 181 via contact 184. Contact 184 includes the first contact 185 and the second contact 186. The first contact 185 connects to the P type floating layer 190b inside the annular trench electrode 260. The second contact 186 connects to the P type floating layer 190b between adjacent annular trench electrodes 260.

The first contact 185 is not connected to the trench electrode 260. In the main junction region CON, the trench electrode 260 is connected to either the first contact 145 or contact 144. On the other hand, in the termination region TER, the trench electrode 260 is not connected to the first contact 185. Therefore, the trench electrode 260 can maintain the emitter potential. Furthermore, the termination wiring 181 including the first contact 185 can be maintained in a floating state.

In the semiconductor device 2, the contact 184, which includes the first contact 185 and the second contact 186, extends in the X-axis direction in which the trench electrode 260 extends. Therefore, it is possible to suppress the connection of the P type floating layer 190b to the trench electrode 260 and to prevent the P-type floating layer 190b from becoming the emitter potential.

In the termination region TER, the semiconductor substrate 150 may have a P type contact layer 194 provided on the surface 151 side, above the P type floating layer 190b. The P type contact layer 194 contains a higher concentration of P type impurities than the P type floating layer 190b. The P type contact layer 194 includes a first contact layer 195 and a second contact layer 196. The first contact layer 195 is located inside the annular trench electrode 260. The second contact layer 196 is placed between adjacent annular trench electrodes 260. The first contact 185 is connected to the P type floating layer 190b through the first contact layer 195. The second contact 186 is connected to the P type floating layer 190b through the second contact layer 196.

According to the semiconductor device 2 of this embodiment, since the trench electrode 260 extends to the P type floating layer 190b, it is possible to extend the electric field relaxation region to the second FLR in the termination region TER. The interval of the FLR may widen towards the outer periphery of the semiconductor device 2. In that case, it is considered that the electric field strength relative to the trench electrode 260 increases. Therefore, by making the trench electrode 260 the emitter potential, it is possible to relax the electric field, improve the collector withstand voltage, and enable shrinking. Thus, it is possible to optimize the relaxation of the electric field by the trench electrode 260 at intervals corresponding to the FLR. When the interval of the FLR is fixed, the range from ring layer p0 to ring layer p1 or about ring layer p2 becomes a high electric field. Therefore, by extending the trench electrode 260 to such a high electric field range, it is possible to alleviate electric field concentration.

### Third Embodiment

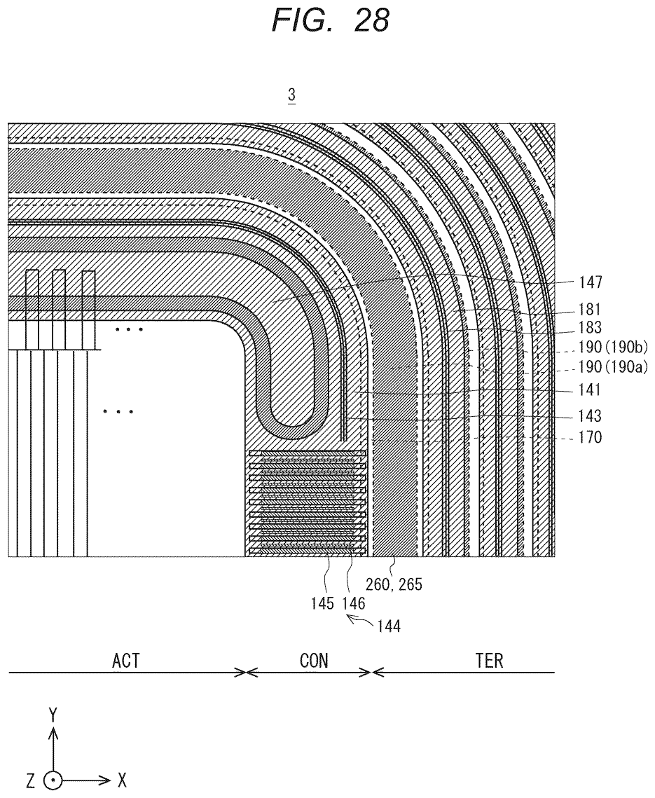

Describes a semiconductor device according to third embodiment. FIG. 28 is a plan view illustrating a semiconductor device 3 according to third embodiment. As shown in FIG. 28, in the semiconductor device 3 of this embodiment, the end of the trench electrode 260 on the termination region TER side is located in the P type junction impurity layer 170 in the main junction region CON. Therefore, both ends in the X-axis direction of the trench electrode 260 are located in the main junction region CON. The contact 144 may include a first contact 145 and a second contact 146. The contact 144 connects to the trench electrode 260 and the P type junction impurity layer 170. Even with such a configuration, it is possible to alleviate electric field concentration.

The disclosure made by the inventor has been specifically described based on the embodiments, but it goes without saying that the disclosure is not limited to the described embodiments and modifications, and various changes can be made without departing from the gist thereof. For example, combinations of the configurations of first to third embodiments and first to third Modifications are also within the scope of the technical concept of the embodiments. Furthermore, the following configurations are also within the scope of the technical concept of the embodiments.

### (Note 1)

A semiconductor device, comprising:
a semiconductor substrate having a first main surface and a second main surface opposite the first main surface; and an emitter wiring provided on the first main surface via an insulating film,
wherein when viewed from the first main surface side, the semiconductor substrate includes:
   an active region includes a plurality of IGBTs formed on the semiconductor substrate;
   a termination region arranged to surround the active region; and
   a main junction region arranged between the active region and the termination region,
wherein the semiconductor substrate of the main junction region includes:
   a drift layer of a first conductivity type; and
   a junction impurity layer of a second conductivity type provided closer to the first main surface side than the drift layer,
wherein the semiconductor substrate in the termination region includes:
   the drift layer; and
   a floating layer of the second conductivity type provided closer to the first main surface side than the drift layer,
wherein at least the main junction region of the semiconductor substrate includes:
   a trench electrode provided inside a trench formed in the first main surface; and
   a trench insulating film provided between the trench electrode and the semiconductor substrate,
wherein when viewed from the first main surface side, the trench electrode includes a portion extending in one direction from the active region towards the termination region, and
wherein the trench electrode and the junction impurity layer are connected to the emitter wiring in the main junction region,
wherein the IGBT comprises:
   the drift layer;
   a barrier layer of the first conductivity type provided closer to the first main surface side than the drift layer;
   a channel layer of the second conductivity type provided closer to the first main surface side than the barrier layer;
   an emitter layer of the first conductivity type provided closer to the first main surface side than the channel layer;
   gate trench electrodes provided so as to sandwich the barrier layer, the channel layer, and the emitter layer in another direction crossing the one direction in a plane parallel to the first main surface; and
   a gate trench insulating film provided between each of the gate trench electrodes and the semiconductor substrate.

### (Note 2)

A semiconductor device according to Note 1, further comprising:
a gate wiring provided on the first main surface via the insulating film,
wherein when viewed from the first main surface side, the semiconductor substrate includes a gate wiring region arranged between the main junction region and the active region in the one direction, and
wherein the gate trench electrode is connected to the gate wiring in the gate wiring region.

### (Note 3)

A semiconductor device according to Note 2,
wherein when viewed from the first main surface side, the trench electrode includes a portion extending from the gate wiring region to the termination region, and
wherein one end of the trench electrode in the one direction is located in the gate wiring region, and the other end is located in the termination region.

### (Note 4)

A semiconductor device according to Note 2,
wherein when viewed from the first main surface side, the trench electrode includes a portion extending from the gate wiring region to the main junction region, and
wherein one end of the trench electrode in the one direction is located in the gate wiring region, and the other end is located in the main junction region.

What is claimed is:

1. A semiconductor device, comprising:
a semiconductor substrate having a first main surface and a second main surface opposite the first main surface; and
an emitter wiring provided on the first main surface via an insulating film,
wherein when viewed from the first main surface side, the semiconductor substrate includes:
an active region includes a plurality of IGBTs formed on the semiconductor substrate;
a termination region arranged to surround the active region; and
a main junction region arranged between the active region and the termination region,
wherein the semiconductor substrate of the main junction region includes:
a drift layer of a first conductivity type; and
a junction impurity layer of a second conductivity type provided closer to the first main surface side than the drift layer,
wherein the semiconductor substrate in the termination region includes:
the drift layer; and
a floating layer of the second conductivity type provided closer to the first main surface side than the drift layer,
wherein at least the main junction region of the semiconductor substrate includes:
a trench electrode provided inside a trench formed in the first main surface; and
a trench insulating film provided between the trench electrode and the semiconductor substrate,
wherein when viewed from the first main surface side, the trench electrode includes a portion extending in one direction from the main junction region towards the termination region, and
wherein the trench electrode and the junction impurity layer are connected to the emitter wiring in the main junction region.

2. The semiconductor device according to claim 1, wherein when viewed from the first main surface side, both ends in the one direction of the trench electrode are located in the main junction region.

3. The semiconductor device according to claim 1,
wherein when viewed from the first main surface side, the trench electrode includes a portion extending from the main junction region to the termination region, and
wherein one end in the one direction of the trench electrode is located in the main junction region, and the other end is located in the termination region.

4. The semiconductor device according to claim 3,
wherein the termination region has a plurality of floating layers including portions extending in another direction crossing the one direction,
wherein the plurality of floating layers includes:
a first floating layer closest to the main junction region; and
a second floating layer next to the first floating layer, and
wherein the other end is located in the first floating layer.

5. The semiconductor device according to claim 3,
wherein the termination region has a plurality of floating layers including portions extending in another direction crossing the one direction,
wherein the plurality of floating layers includes:
a first floating layer closest to the main junction region; and
a second floating layer next to the first floating layer, and
wherein the other end is located in the second floating layer.

6. The semiconductor device according to claim 1, wherein the floating layer is not connected to the emitter wiring in the termination region.

7. The semiconductor device according to claim 1,
wherein the emitter wiring includes:
a main body portion; and
an emitter contact connecting to the junction impurity layer, and
wherein the junction impurity layer is connected to the emitter wiring through the emitter contact.

8. The semiconductor device according to claim 7,
wherein the trench includes a plurality of trenches,
wherein the trench electrode includes a plurality of trench electrodes each of which is provided in one of the trenches,
wherein when viewed from the first main surface side, each of the trench electrodes and each of the trenches are annular,
wherein the emitter contact includes:
a first emitter contact connecting to the junction impurity layer inside the annular trench electrode; and
a second emitter contact connecting to the junction impurity layer between two adjacent annular trench electrodes.

9. The semiconductor device according to claim 8,
wherein the semiconductor substrate in the main junction region includes an emitter contact layer of the second conductivity type provided closer to the first main surface side than the junction impurity layer, the emitter contact layer containing a higher concentration of the second conductivity type impurity than the junction impurity layer,
wherein the emitter contact layer includes:
a first emitter contact layer arranged inside the annular trench electrode; and
a second emitter contact layer arranged between the two adjacent annular trench electrodes,
wherein the first emitter contact is connected to the junction impurity layer through the first emitter contact layer, and
wherein the second emitter contact is connected to the junction impurity layer through the second emitter contact layer.

10. The semiconductor device according to claim 9,
wherein an upper end on the first main surface side of the trench electrode has a step relative to a lower end on the second main surface side of the first emitter contact, and
wherein the trench electrode is connected to the emitter wiring through the step.

11. The semiconductor device according to claim 7,
wherein the trench includes a plurality of trenches,
wherein the trench electrode includes a plurality of trench electrodes each of which is provided in one of the trenches,
wherein when viewed from the first main surface side, each of the trench electrodes and each of the trenches are annular, and
wherein the emitter contact is formed across the plurality of annular trench electrodes and the junction impurity layer.

12. The semiconductor device according to claim 11,
wherein the semiconductor substrate in the main junction region includes an emitter contact layer of the second conductivity type provided closer to the first main surface side than the junction impurity layer, the emitter contact layer containing a higher concentration impurity of the second conductivity type than the junction impurity layer,
wherein the emitter contact layer includes:
a first emitter contact layer arranged inside the annular trench electrode; and
a second emitter contact layer arranged between the two adjacent annular trench electrodes,
wherein the emitter contact is connected to the junction impurity layer through the first and second emitter contact layers.

13. The semiconductor device according to claim 12, wherein an upper end on the first main surface side of the trench electrode is connected to a lower end of the emitter contact.

14. The semiconductor device according to claim 1, wherein the IGBT comprises:
the drift layer;
a barrier layer of the first conductivity type provided closer to the first main surface side than the drift layer;
a channel layer of the second conductivity type provided closer to the first main surface side than the barrier layer;
an emitter layer of the first conductivity type provided closer to the first main surface side than the channel layer;
gate trench electrodes provided so as to sandwich the barrier layer, the channel layer, and the emitter layer in one direction in a plane parallel to the first main surface;
a gate trench insulating film provided between each of the gate trench electrodes and the semiconductor substrate; and
an IGBT floating layer of the second conductivity type provided on the opposite side of the barrier layer, the channel layer, and the emitter layer across the gate trench electrode.

15. The semiconductor device according to claim 1,
wherein when viewed from the first main surface side, the main junction region includes:
a first main junction portion extending in the one direction;
a second main junction portion extending in a second direction crossing the one direction; and
a third main junction portion at the corner where the first and second main junction portions are connected, and
wherein the trench electrode includes a portion extending in either the one direction or the second direction at the third main junction portion.

16. The semiconductor device according to claim 15,
wherein when viewed from the first main surface side, the termination region includes:
a first termination portion extending in the one direction;
a second termination portion extending in the second direction; and
a third termination portion at a corner where the first and second termination portions are connected, and
wherein the trench electrode includes a portion extending from the third main junction portion to the third termination portion.

17. The semiconductor device according to claim 5, further comprising:
wherein in the termination region, a termination wiring provided on the first main surface via an insulating film,
wherein the termination wiring includes:
a body portion; and
a termination contact connecting to the second floating layer, and
wherein the second floating layer is connected to the termination wiring via the termination contact.

18. The semiconductor device according to claim 17,
wherein the trench includes a plurality of trenches,
wherein the trench electrode includes a plurality of trench electrodes each of which is provided in one of the trenches,
wherein when viewed from the first main surface side, each of the trench electrodes and each of the trenches are annular, and
wherein the termination contact includes:
a first termination contact connecting to the second floating layer inside the annular trench electrode, and
a second termination contact connecting to the second floating layer between two adjacent annular trench electrodes.

19. The semiconductor device according to claim 18,
wherein the semiconductor substrate in the termination region includes a termination contact layer of the second conductivity type provided closer to the first main surface side than the second floating layer, the termination contact layer containing a higher concentration impurity of the second conductivity type than the second floating layer,
wherein the termination contact layer includes:
a first termination contact layer arranged inside the annular trench electrode; and
a second termination contact layer arranged between two adjacent annular trench electrodes, and
wherein the first termination contact is connected to the second floating layer via the first termination contact layer, and
wherein the second termination contact is connected to the second floating layer via the second termination contact layer.

20. The semiconductor device, comprising:
a semiconductor substrate having a first main surface and a second main surface opposite the first main surface; and
an emitter wiring provided on the first main surface via an insulating film,
wherein when viewed from the first main surface side, the semiconductor substrate includes:
an active region includes a plurality of IGBTs formed on the semiconductor substrate;
a termination region arranged to surround the active region; and
a main junction region arranged between the active region and the termination region,
wherein the semiconductor substrate of the main junction region includes:
a drift layer of a first conductivity type; and
a junction impurity layer of a second conductivity type provided closer to the first main surface side than the drift layer,
wherein the semiconductor substrate in the termination region includes:
the drift layer; and
a floating layer of the second conductivity type provided closer to the first main surface side than the drift layer,
wherein at least the main junction region of the semiconductor substrate includes:
a trench electrode provided inside a trench formed in the first main surface; and
a trench insulating film provided between the trench electrode and the semiconductor substrate,
wherein when viewed from the first main surface side, the trench electrode includes a portion extending in one direction from the main junction region towards the termination region,
wherein the trench electrode and the junction impurity layer are connected to the emitter wiring in the main junction region, and
wherein the IGBT comprises:
the drift layer;
a barrier layer of the first conductivity type provided closer to the first main surface side than the drift layer;
a channel layer of the second conductivity type provided closer to the first main surface side than the barrier layer;
an emitter layer of the first conductivity type provided closer to the first main surface side than the channel layer;
gate trench electrodes provided so as to sandwich the barrier layer, the channel layer, and the emitter layer in another direction crossing the one direction in a plane parallel to the first main surface;
a gate trench insulating film provided between each of the gate trench electrodes and the semiconductor substrate; and
an IGBT floating layer of the second conductivity type provided on the opposite side of the barrier layer, the channel layer, and the emitter layer across the gate trench electrode.
